(19) United States
(12) Patent Application Publication
(10) Pub. No.: US 2014/0293560 A1
(43) Pub. Date: Oct. 2, 2014

(54) SUBSTRATE EMBEDDING ELECTRONIC COMPONENT AND METHOD OF MANUFACTURING SUBSTRATE EMBEDDING ELECTRONIC COMPONENT

(71) Applicant: SAMSUNG ELECTRO-MECHANICS CO., LTD., Suwon-si (KR)

(72) Inventor: Sang Chul LEE, Yeongi-gun (KR)

(73) Assignee: SAMSUNG ELECTRO-MECHANICS CO., LTD., Suwon-si (KR)

(21) Appl. No.: 14/226,375

(22) Filed: Mar. 26, 2014

(30) Foreign Application Priority Data
Mar. 27, 2013 (KR) 10-2013-0032918

(51) Int. Cl. H05K 1/18

(52) U.S. Cl. CPC H05K 1/186
USPC 361/761; 156/182

(57) ABSTRACT

Disclosed herein is a substrate embedding an electronic component and a method of manufacturing the substrate embedding an electronic component, the substrate embedding an electronic component including a first insulating part having the electronic component positioned therein, the electronic component being provided with terminals on a surface thereof; a first pattern layer provided at a lower portion of the first insulating part; a second pattern layer provided at an upper portion of the first insulating part; and a conductive film structure provided between at least one the first and second pattern layers and the terminal and electrically connecting the pattern layer to the terminal, and being advantageous for a decrease of the number of layers of a structure of the substrate embedding an electronic component and slimness.

### CROSS REFERENCE(S) TO RELATED APPLICATIONS

This application claims the benefit under 35 U.S.C. Section 119 of Korean Patent Application Serial No. 10-2013-0032918, entitled “Substrate Embedding Electronic Component and Method of Manufacturing Substrate Embedding Electronic Component” filed on Mar. 27, 2013, which is hereby incorporated by reference in its entirety into this application.

### BACKGROUND OF THE INVENTION

1. Technical Field

The present invention relates to a substrate embedding an electronic component and a method of manufacturing the substrate embedding an electronic component.

2. Description of the Related Art

In accordance with a development of an electronics industry, a demand for high function and miniaturization of an electronic component has gradually increased, and particularly, a flow of market based on slimness and lightness of a personal digital terminal has continued toward thinness of circuit substrate.

Therefore, a method of mounting elements different from a method of mounting elements according to the related art has been proposed.

For example, an attempt of performing high densification of the circuit substrate to which various electronic components are coupled by mounting active devices such as an integrated chip (IC) or passive devices such as a capacitor of a multi-layer ceramic capacitor (MLCC) type in the circuit substrate and improving performance of an electronic component package itself by improving reliability has been continuously conducted.

The substrate in which the electronic component is embedded refers to an embedded circuit substrate, and has been highlighted as a part of the next generation of multi-function and small package technologies.

As an example, Patent Document 1 discloses the circuit substrate in which the electronic component is embedded.

For example, in the case in which the multi-layer ceramic capacitor (MLCC) is embedded in the circuit substrate, an external electrode of the MLCC may be connected to a circuit pattern of the circuit substrate through a via. However, as a size of the MLCC is minimized, it is difficult to form the external electrode connected to the via so as to have a uniform shape. Therefore, a problem of reliability of a connection to the via, or the like may be generated.

In addition, in order to embed the electronic component in the circuit substrate as described above, a method of including a cavity in a core layer to receive the electronic component, including insulating layers covering the core layer and the electronic component on upper and lower portions of the core layer, and connecting the embedded electronic component to an outside of the insulation layer by the via has been generally used.

However, according to the above-mentioned method, since at least three or more insulation layers are required, there was a limitation in decreasing the number of layers and furthermore, there was a limitation in decreasing a thickness of the substrate embedding an electronic component.

### RELATED ART DOCUMENT

### Patent Document

(Patent Document 1) US Patent Laid-Open Publication No. 2012-0006469

### SUMMARY OF THE INVENTION

An object of the present invention is to provide a substrate embedding an electrode component advantageous for slimness.

In addition, an object of the present invention is to provide a method of manufacturing the substrate embedding an electrode component advantageous for slimness.

According to an exemplary embodiment of the present invention, there is provided a substrate embedding an electronic component, including: a first insulating part having the electronic component positioned therein, the electronic component being provided with terminals on a surface thereof; a first pattern layer provided at a lower portion of the first insulating part; a second pattern layer provided at an upper portion of the first insulating part; and a conductive film structure provided between at least one the first and second pattern layers and the terminal and electrically connecting the pattern layer to the terminal.

At least one of the first pattern layer and the second pattern layer may include an inner layer pattern formed to be protruded in an inner side direction of the first insulating part and an outer layer pattern formed to be protruded in an outer side direction of the first insulating part, and the conductive film structure may have one surface contacting with the outer layer pattern and the other surface contacting with the terminal.

The substrate embedding an electronic component may further include: a second insulating part covering the first insulating part and the first pattern layer; a first via contacting with the first pattern layer by penetrating through the second insulating part; a third insulating part covering the first insulating part and the second pattern layer; and a second via contacting with the second pattern layer by penetrating through the third insulating part.

The first pattern layer may include first inner layer patterns formed to be protruded in an inner side direction of the first insulating part and first outer patterns formed to be protruded in an outer side direction of the first insulating part, the second pattern layer may include second inner layer patterns formed to be protruded in the inner side direction of the first insulating part and second outer patterns formed to be protruded in the outer side direction of the first insulating part, and the conductive film structure may have one surface contacting with at least one of the first outer layer pattern and the second outer layer pattern, and the other surface contacting with the terminal, the substrate may further include a through via electrically connecting between the first outer layer pattern and the second outer layer pattern by penetrating through the first insulating part.

The conductive film structure may be formed of an anisotropic conductive film including an adhesive resin and conductive particles.

According to another exemplary embodiment of the present invention, there is provided a substrate embedding an electronic component, including: an electronic component having a body part provided with terminals on a surface thereof; first inner layer patterns provided under the electronic component; second inner layer patterns provided over the electronic component; a first insulating part provided between the first inner layer patterns, between the second inner layer patterns, and between the first inner layer pattern and the second inner layer pattern, and covering the electronic component; a first outer layer pattern formed on a surface including a lower surface of the first insulating part and a lower surface of the first inner layer pattern; a second outer layer pattern formed on a surface including an upper surface of the first insulating part and an upper surface of the first inner layer pattern; and a conductive film structure provided between the first outer layer pattern or the second outer layer pattern and the terminal.

The substrate embedding an electronic component may further include: a second insulating part covering the first insulating part and the first outer layer pattern; a third insulating part covering the first insulating part and the second outer layer pattern; a first via contacting with the first pattern layer by penetrating through the second insulating part; and a second via contacting with the second pattern layer by penetrating through the third insulating part.

The substrate embedding an electronic component may further include a through via electrically connecting between the first outer layer pattern and the second outer layer pattern by penetrating through the first insulating part.

The conductive film structure may be formed of an anisotropic conductive film including an adhesive resin and conductive particles.

According to still another exemplary embodiment of the present invention, there is provided a method of manufacturing a substrate embedding an electronic component, including: providing a first detach core having a first inner layer pattern provided on an upper surface thereof and a second detach core having a second inner layer pattern provided on a lower surface thereof; coupling an electronic component having terminals on a surface thereof to the upper surface of the first detach core, wherein a conductive film structure being provided between the terminal and the upper surface of the first detach core; forming a first insulating part by positioning an insulating material over the electronic component, positioning the second detach core over the insulating material, and compressing the insulating material and the second detach core in a direction in which a distance between the first inner layer pattern and the second inner layer pattern is decreased; separating the first inner layer pattern from the first detach core and separating the second inner layer pattern from the second detach core; forming a first plating layer covering a lower surface of the first insulating part and a lower surface of the first inner layer pattern, and a second plating layer covering an upper surface of the first insulating part and an upper surface of the second inner layer pattern; and forming a first outer layer pattern by patterning the first plating layer and forming a second outer layer pattern by patterning the second plating layer.

The conductive film structure may have one surface contacting with the first outer layer pattern and the other surface contacting with the terminal.

The method may further include forming a second insulating part covering the first insulating part and the first outer layer pattern and forming a third insulating part covering the first insulating part and the second outer layer pattern.

The method may further include forming a first via contacting with the first pattern layer by penetrating through the second insulating part and forming a second via contacting with the second pattern layer by penetrating through the third insulating part.

The conductive film structure may be formed of an anisotropic conductive film including an adhesive resin and conductive particles.

### BRIEF DESCRIPTION OF THE DRAWINGS

FIG. 1A is a cross-sectional view schematically showing a substrate embedding an electronic component according to an exemplary embodiment of the present invention;

FIG. 1B is a view illustrating a comparative example of FIG. 1A;

FIG. 2 is a view schematically illustrating a principle of electrically connecting the electronic component in the substrate embedding an electronic component according to the exemplary embodiment of the present invention;

FIG. 3A is a view schematically illustrating one process of a method of manufacturing a substrate embedding an electronic component according to an exemplary embodiment of the present invention;

FIG. 3B is a view schematically illustrating one process of a method of manufacturing a substrate embedding an electronic component according to an exemplary embodiment of the present invention;

FIG. 4 is a view schematically illustrating a process of mounting an electronic component of the method of manufacturing the substrate embedding an electronic component according to the exemplary embodiment of the present invention; and

FIG. 5 is a view schematically illustrating a process of forming an outer layer pattern of the method of manufacturing the substrate embedding an electronic component according to the exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Like reference numerals denote like elements throughout the description.

Terms used in the present specification are for explaining exemplary embodiments rather than limiting the present invention. Unless specifically mentioned otherwise, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but is not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

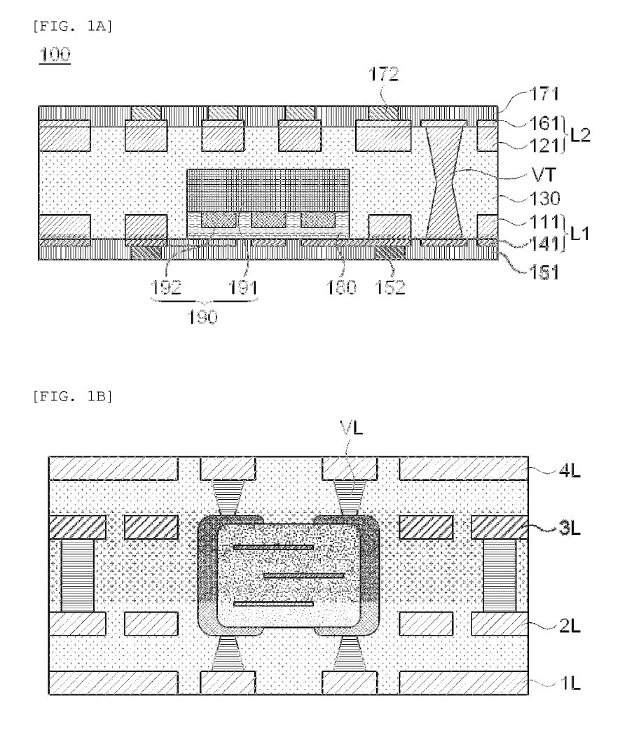

FIG. 1A is a cross-sectional view schematically showing a substrate 100 embedding an electronic component according to an exemplary embodiment of the present invention.

Referring to FIG. 1A, the substrate 100 embedding an electronic component may include a first insulating part 130, a first pattern layer L1, a second pattern layer L2, and a conductive film structure 180.

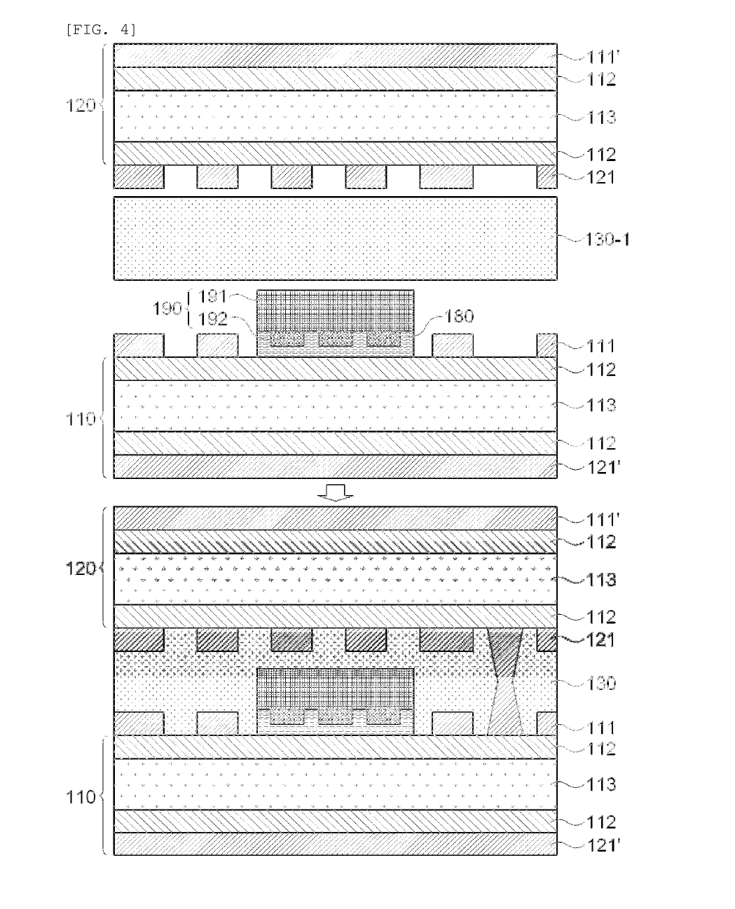

The first insulating part 130 may be made of a typical insulating material (130-1 of FIG. 4) and may accommodate an electronic component 190 therein by being provided between the first pattern layer L1 and the second pattern layer L2.

In the drawing, it is illustrated that the first pattern layer L1 is positioned at a lower portion of the first insulating part 130 and the second pattern layer L2 is positioned at an upper portion of the first insulating part 130.

The first pattern layer L1 may include a first inner layer pattern 111 and a first outer layer pattern 141, and the second pattern layer L2 may include a second inner layer pattern 121 and a second outer layer pattern 161.

In this case, the first inner layer pattern 111 and the second inner layer pattern 121 are formed to be protruded in an inner side direction of the first insulating part 130. That is, the first inner layer pattern 111 and the second inner layer pattern 121 are protruded in a direction facing each other so as to be inserted into the inner side of the insulating part 130.

On the other hand, the first outer layer pattern 141 and the second outer layer pattern 161 are formed to be protruded in an outer side direction of the first insulating part 130.

Meanwhile, FIG. 1A illustrates a case in which terminals 192 of the electronic component 190 are formed to be protruded from a lower surface of a body part 191, the conductive film structure 180 is coupled to a lower surface of the electronic component 190 including the terminals 192, and the first outer layer pattern 141 contacts with a lower surface of the conductive film structure 180.

However, this illustrates an exemplary embodiment of the present invention. It will be apparent that although not shown, the terminals 192 may be formed to be protruded from an upper surface of the body part 191, the conductive film structure 180 may be coupled to an upper surface of the electronic component 190 including the terminals 192, and the first outer layer pattern 161 may be connected to an upper surface of the conductive film structure 180.

Furthermore, the terminals 192 may be formed to be protruded from both the upper and lower surfaces of the body part 191, the conductive film structure 180 may be provided to both the upper and lower parts of the electronic component 190, the conductive film structure 180 may contact with the first outer layer pattern 141 and the second outer layer pattern 161, respectively. The above-mentioned configuration may be usefully applied in the case in which the electronic component 190 is particularly passive devices such as an MLCC.

Here, as illustrated in FIG. 1A, the conductive film structure 180 coupled to the terminal 192 of the electronic component 190 is positioned at a portion at which the first inner layer pattern 111 is not formed to thereby enable the first outer layer pattern 141 and the conductive film structure 180 to directly contact each other.

Therefore, the substrate 100 embedding an electronic component may have a thickness slimmed by a thickness of the first inner layer pattern 111 as compared to a case in which the electronic component 190 is positioned on a vertical extension line between the upper surface of the first inner layer pattern 111 and the lower surface of the second inner layer pattern 121.

Meanwhile, a second insulating part 151 covering the lower surface of the first insulating part 130 and the first pattern layer L1 is further provided, thereby making it possible to secure insulation between the first pattern layer L1 and the outside of the substrate 100 embedding an electronic component.

Furthermore, a first via 152 contacting with the first pattern layer L1 by penetrating through the second insulating part 151 is provided to enable the substrate 100 embedding an electronic component to electrically be connected to a predetermined external device, and the like.

In addition, a third insulating part 171 covering the upper surface of the first insulating part 130 and the second pattern layer L2, a second via 172, and the like may be further provided.

FIG. 1B is a view illustrating a comparative example of FIG. 1A.

As illustrated in FIG. 1, in the case in which the electronic component is embedded in the substrate, in order to electrically connect the electronic component embedded in the substrate to the outside of the substrate, a via V is generally provided.

In addition, the number of conductive pattern layers provided on a surface of and in a multi-layer substrate is typically defined as the number of layers of the multi-layer substrate and a structure of the substrate embedding an electronic component is generally implemented by at least four layers (1L, 2L, 3L, 4L) as illustrated in FIG. 1B for the purpose of efficiency of a process embedding the electronic component, a warpage decrease, and the like.

Therefore, the general structure of the substrate embedding an electronic component as illustrated in FIG. 1B had a limitation in decreasing the number of layers thereof and also had a limitation in slimming the entire thickness of the substrate structure.

In addition, in order to electrically connect the embedded electronic component to the outside, the via V contacting with the terminal of the surface of the electronic component needs to be provided. However, since the electronic component has been recently miniaturized, it is difficult to precisely perform a process forming the via capable of stably contacting with the terminal of the electronic component. As a result, a problem causing an erroneous via connection, or the like is generated.

However, the substrate 100 embedding an electronic component according to the exemplary embodiment of the present invention may implement the structure of the substrate embedding an electronic component 190 only using the first insulating part 130 of one layer and the pattern layers L1 and L2 of two layers.

Therefore, the structure of the substrate embedding an electronic component 190 may be implemented by two layers structure unlike the case of the comparative example illustrated in FIG. 1B, such that the substrate 100 embedding an electronic component is advantageously slimmed and efficiency of a manufacturing process may be further increased.

In addition, since the via directly contacting with the electronic component 190 is unnecessary, in the case in which a subminiature electronic component 190 such as the MLCC is embedded in the substrate, connection precision may be significantly improved as compared to the method according to the comparative example illustrated in FIG. 1B.

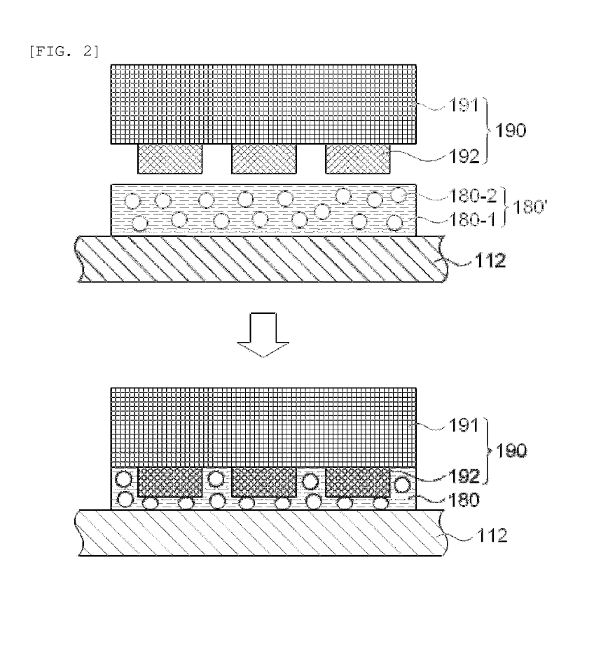

FIG. 2 is a view schematically illustrating a principle of electrically connecting the electronic component 190 in the substrate 100 embedding an electronic component according to the exemplary embodiment of the present invention.

Referring to FIG. 2, an anisotropic conductive film 180′ (ACF) typically means a film state manufactured by mixing conductive particles 180-2 having a micro-size in an adhesive resin 180-1 and may couple two objects by compressing two objects in a state in which two objects are positioned on both sides of the anisotropic conductive film 180′.

In this case, as shown in FIG. 2, in the case in which a surface contacting with the anisotropic conductive film 180′ has concave and convex parts, or the like, a vertical and downward portion of a convex part of the anisotropic conductive film 180′ is concentrated with the conductive particles 180-2, thereby making it possible to secure conductivity and a vertical and downward portion of a concave part may secure insulation.

The substrate 100 embedding an electronic component according to the exemplary embodiment of the present invention may electrically connect the terminal 192 of the electronic component 190 to the pattern layer using the above-mentioned anisotropic conductive film 180′. However, although FIG. 2 illustrates a case in which a carrier copper foil 112 of a detach core to be described below contacts with the other surface of the conductive film structure 180, the first outer layer pattern 141 may contact with the other surface of the anisotropic conductive film structure 180′ by the following process.

Meanwhile, the present specification has represented the structure in which the anisotropic conductive film 180′ is positioned and compressed between the objects having the concave and convex parts, or the like, to thereby electrically conduct the convex part by the anisotropic conductive film 180′, as the conductive film structure 180.

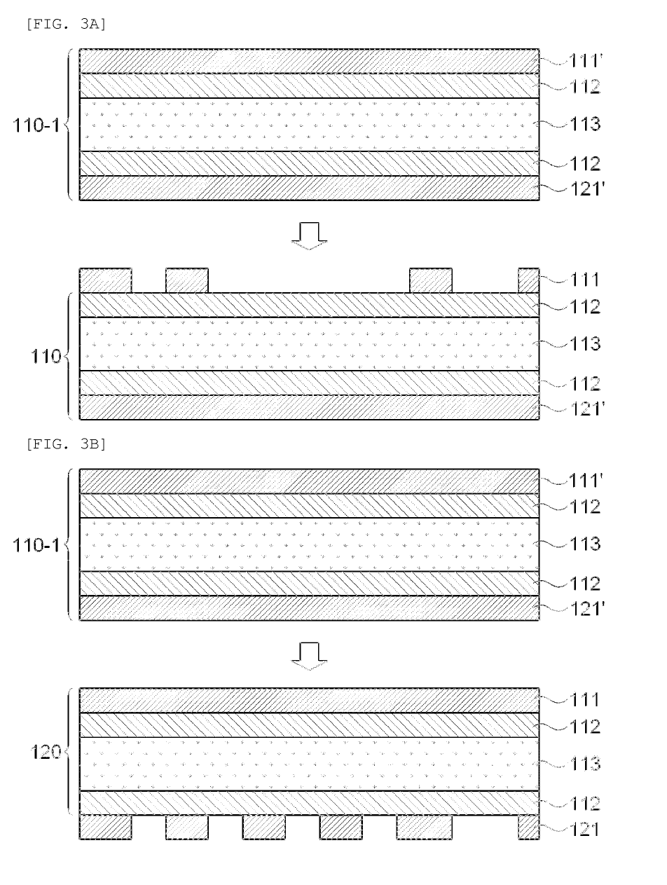

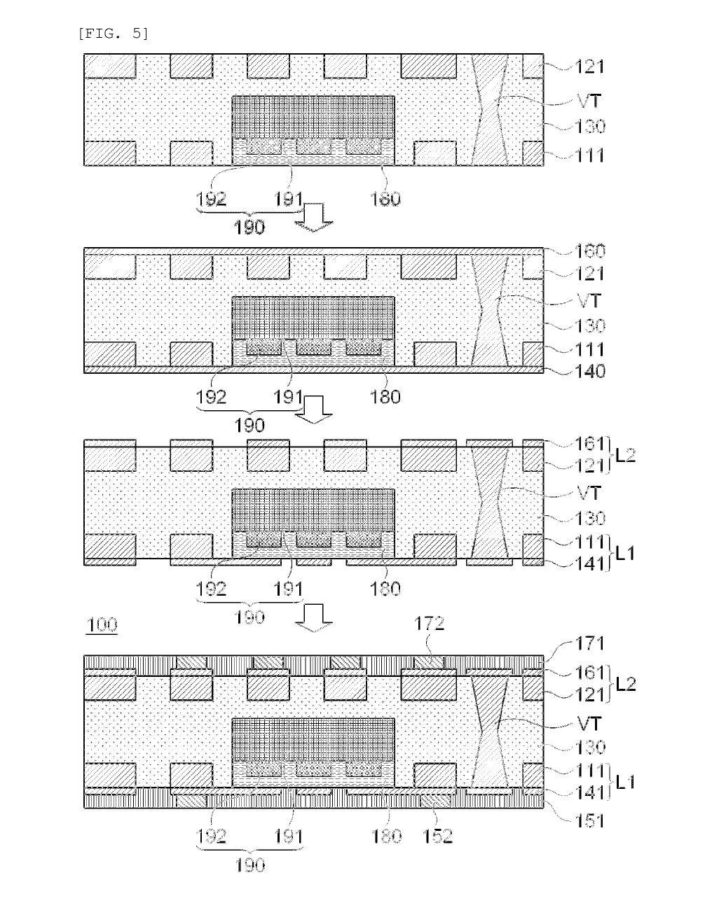

FIG. 3A is a view schematically illustrating one process of a method of manufacturing a substrate 100 embedding an electronic component according to an exemplary embodiment of the present invention, FIG. 3B is a view schematically illustrating one process of a method of manufacturing a substrate 100 embedding an electronic component according to an exemplary embodiment of the present invention, FIG. 4 is a view schematically illustrating a process of mounting an electronic component 190 of the method of manufacturing the substrate 100 embedding an electronic component according to the exemplary embodiment of the present invention, and FIG. 5 is a view schematically illustrating a process of forming an outer layer pattern of the method of manufacturing the substrate 100 embedding an electronic component according to the exemplary embodiment of the present invention.

Referring to FIGS. 3A to 5, the method of manufacturing the substrate 100 embedding an electronic component according to the exemplary embodiment of the present invention may be performed in a way in which the insulating material 130-1, the electronic component 190, and the anisotropic conductive film 180′ are positioned and compressed between a first detach core 110 and a second detach core 120, and the first detach core 110 and the second detach core 120 are then separated.

The detach core in the present specification means one that one surface of a laminate 110-1 is patterned so as to form an inner layer pattern.

In addition, the laminate 110-1 means one that the carrier copper foil 112 is provided on one surface or both surfaces of the insulating layer 113 and a thin type copper foil 111′ is provided on an outer surface of the carrier copper foil 112.

That is, as illustrated in FIG. 3A, one that the thin type copper foil 111′ provided on an upper portion of the laminate 110-1 is patterned so as to form the first inner layer pattern 111 may be the first detach core 110, and on the other hand, as illustrated in FIG. 3B, one that the thin type copper foil 111′ provided on a lower portion of the laminate 110-1 is patterned so as to form the second inner layer pattern 121 may be the second detach core 120.

Referring to FIG. 4, the electronic component 190 is mounted so that the conductive film structure 180 contacts with an upper surface of the first detach core 110 and the lower surface of the electronic component 190 including the terminal 192 contacts with an upper surface of the conductive film structure 180.

Next, the second detach core 120 is compressed in a direction of the first detach core 110 in a state in which the insulating material 130-1 is positioned above the electronic component 190 and the second detach core 120 is positioned over the insulating material 130-1.

Referring to FIG. 5, first, a lower surface of the first inner layer pattern 111 is separated from the first detach core 110 and an upper surface of the second inner layer pattern 121 is separated from the second detach core 120.

That is, the carrier copper foils 112 each contacting with the first inner layer pattern 111 and the second inner layer pattern 121 each are removed.

Next, a first plating layer 140 is formed on a surface including the lower surface of the first insulating part 130 and the lower surface of the first inner layer pattern 111. In this case, a second plating layer 160 may be formed on a surface including the upper surface of the second insulating part 151 and the upper surface of the second inner layer pattern 121.

Next, the first plating layer 140 and the second plating layer 160 are patterned so as to form the first outer layer pattern 141 and the second outer layer pattern 161, respectively.

Meanwhile, before forming the first plating layer 140 and the second plating layer 160, a through via VT may be formed by processing a via hole penetrating through the first insulating part 130 and by providing a conductive material to the via hole, as needed. The through via formed as described above may serve to electrically connect the first outer layer pattern 141 to the second outer layer pattern 161.

Meanwhile, a second insulating part 151 and a third insulating part 171 may be formed by covering the first outer layer pattern 141 and the second outer layer pattern 161 with the insulating material.

In addition, a first via 152 and a second via 172 penetrating through each of the second insulating part 151 and the third insulating part 171 to be each connected to the first outer layer pattern 141 and the second outer layer pattern 161 may be formed.

Therefore, efficiency of manufacturing the substrate 100 embedding an electronic component may be improved as compared to the case of manufacturing the above described comparative example illustrated in FIG. 1B. In addition, since the via directly contacting with the terminal 192 of the electronic component 190 does not need to be provided, electrical connection reliability of the electronic component 190 embedded in the substrate may be improved.

The substrate embedding an electronic component according to an exemplary embodiment of the present invention may implement a slimmer substrate structure capable of electrically connecting the embedded electronic component to the outside as compared to the related art.

In addition, the substrate embedding an electronic component according to an exemplary embodiment of the present invention may implement an electrical connection from the electronic component to the outside through the substrate without including a general via according to the related art, such that the number of layers of the substrate in which the electronic component is embedded may be decreased as compared to the related art.

What is claimed is:

1. A substrate embedding an electronic component, comprising:
a first insulating part having the electronic component positioned therein, the electronic component being provided with terminals on a surface thereof;
a first pattern layer provided at a lower portion of the first insulating part;
a second pattern layer provided at an upper portion of the first insulating part; and
a conductive film structure provided between at least one the first and second pattern layers and the terminal and electrically connecting the pattern layer to the terminal.

2. The substrate embedding an electronic component according to claim 1, wherein at least one of the first pattern layer and the second pattern layer includes an inner layer pattern formed to be protruded in an inner side direction of the first insulating part and an outer layer pattern formed to be protruded in an outer side direction of the first insulating part, and
the conductive film structure has one surface contacting with the outer layer pattern and the other surface contacting with the terminal.

3. The substrate embedding an electronic component according to claim 2, further comprising:
a second insulating part covering the first insulating part and the first pattern layer;
a first via contacting with the first pattern layer by penetrating through the second insulating part;
a third insulating part covering the first insulating part and the second pattern layer; and
a second via contacting with the second pattern layer by penetrating through the third insulating part.

4. The substrate embedding an electronic component according to claim 1, wherein the first pattern layer includes first inner layer patterns formed to be protruded in an inner side direction of the first insulating part and first outer patterns formed to be protruded in an outer side direction of the first insulating part,
the second pattern layer includes second inner layer patterns formed to be protruded in the inner side direction of the first insulating part and second outer patterns formed to be protruded in the outer side direction of the first insulating part, and
the conductive film structure has one surface contacting with at least one of the first outer layer pattern and the second outer layer pattern, and the other surface contacting with the terminal,
the substrate further including a through via electrically connecting between the first outer layer pattern and the second outer layer pattern by penetrating through the first insulating part.

5. The substrate embedding an electronic component according to claim 1, wherein the conductive film structure is formed of an anisotropic conductive film including an adhesive resin and conductive particles.

6. A substrate embedding an electronic component, comprising:
an electronic component having a body part provided with terminals on a surface thereof;
first inner layer patterns provided under the electronic component;
second inner layer patterns provided over the electronic component;
a first insulating part provided between the first inner layer patterns, between the second inner layer patterns, and between the first inner layer pattern and the second inner layer pattern, and covering the electronic component;
a first outer layer pattern formed on a surface including a lower surface of the first insulating part and a lower surface of the first inner layer pattern;
a second outer layer pattern formed on a surface including an upper surface of the first insulating part and an upper surface of the first inner layer pattern; and
a conductive film structure provided between the first outer layer pattern or the second outer layer pattern and the terminal.

7. The substrate embedding an electronic component according to claim 6, further comprising:
a second insulating part covering the first insulating part and the first outer layer pattern;
a third insulating part covering the first insulating part and the second outer layer pattern;
a first via contacting with the first pattern layer by penetrating through the second insulating part; and
a second via contacting with the second pattern layer by penetrating through the third insulating part.

8. The substrate embedding an electronic component according to claim 6, further comprising a through via electrically connecting between the first outer layer pattern and the second outer layer pattern by penetrating through the first insulating part.

9. The substrate embedding an electronic component according to claim 6, wherein the conductive film structure is formed of an anisotropic conductive film including an adhesive resin and conductive particles.

10. A method of manufacturing a substrate embedding an electronic component, comprising:
providing a first detach core having a first inner layer pattern provided on an upper surface thereof and a second detach core having a second inner layer pattern provided on a lower surface thereof;
coupling an electronic component having terminals on a surface thereof to the upper surface of the first detach core, wherein a conductive film structure being provided between the terminal and the upper surface of the first detach core;
forming a first insulating part by positioning an insulating material over the electronic component, positioning the second detach core over the insulating material, and compressing the insulating material and the second detach core in a direction in which a distance between the first inner layer pattern and the second inner layer pattern is decreased;
separating the first inner layer pattern from the first detach core and separating the second inner layer pattern from the second detach core;
forming a first plating layer covering a lower surface of the first insulating part and a lower surface of the first inner layer pattern, and a second plating layer covering an upper surface of the first insulating part and an upper surface of the second inner layer pattern; and
forming a first outer layer pattern by patterning the first plating layer and forming a second outer layer pattern by patterning the second plating layer.

11. The method according to claim 10, wherein the conductive film structure has one surface contacting with the first outer layer pattern and the other surface contacting with the terminal.

12. The method according to claim 10, further comprising forming a second insulating part covering the first insulating part and the first outer layer pattern and forming a third insulating part covering the first insulating part and the second outer layer pattern.

13. The method according to claim 12, further comprising forming a first via contacting with the first pattern layer by penetrating through the second insulating part and forming a second via contacting with the second pattern layer by penetrating through the third insulating part.

14. The method according to claim 10, wherein the conductive film structure is formed of an anisotropic conductive film including an adhesive resin and conductive particles.
